(19) United States
(12) Patent Application Publication
(10) Pub. No.: US 2022/0380523 A1
(43) Pub. Date: Dec. 1, 2022

(54) LIGHT-EMITTING COMPOSITION

(71) Applicant: Sumitomo Chemical Co., Ltd., Tokyo (JP)

(72) Inventors: Kiran Kamtekar, Cambridgeshire (GB); Nazrul Islam, Cambridgeshire (GB)

(73) Assignee: Sumitomo Chemical Co., Ltd., Tokyo (JP)

(21) Appl. No.: 17/624,323

(22) PCT Filed: Jul. 3, 2020
(86) PCT No.: PCT/GB2020/051612

§ 371 Date: Dec. 31, 2021

(30) Foreign Application Priority Data
Jul. 3, 2019 (GB) 1909585.0
Mar. 31, 2020 (GB) 2004726.2

(51) Int. Cl. C08G 61/12; H01L 51/00; C09K 11/06

(52) U.S. Cl. CPC C08G 61/126; H01L 51/0035; C09K 11/06

(57) ABSTRACT

A light-emitting composition comprising: a light-emitting group and a polymer comprising: a repeat unit of formula Ar¹ wherein Ar¹ is an arylene repeat unit which is unsubstituted or substituted with one or more substituents; and a repeat unit of formula (I): (I) wherein Ar² and Ar³ each independently represent a C₆₋₂₀ arylene group or a 5-20 membered heteroarylene group which is unsubstituted or substituted with one or more substituents and CB represents a conjugation-breaking group which does not provide a conjugation path between Ar² and Ar³; wherein the polymer has a solubility in water or a C₁₋₈ alcohol at 20° C. of at least 0.1 mg/ml. The composition may be a light-emitting polymer in which the polymer contains the light-emitting group. The light-emitting composition may be part of a particle containing the polymer and a matrix material, e.g. silica. The light-emitting composition may be used in an assay for detection of a target analyte.

### BACKGROUND

Embodiments of the present disclosure relate to light-emitting compositions, including light-emitting polymers, in particular conjugated light-emitting polymers; composite particles containing the same; and the use thereof as a luminescent marker.

Light-emitting polymers have been disclosed as labelling or detection reagents.

J. Mater. Chem., 2013, vol. 1, pp 3297-3304, Behrendt et al. describes silica-LEP nanoparticles where the LEP is covalently bound to the silica. The light emitting polymer has alkoxysilane groups pendant from the polymer backbone which react with the silica monomer during formation of the nanoparticles.

Nanoscale, 2013, vol. 5, pp 8593-8601, Geng et al. describes silica-conjugated polymer (CP) nanoparticles wherein the LEP has pendant non-polar alkyl side chains and where the nanoparticles have a “SiO₂@CP@SiO₂” structure.

Chem. Mater., 2014, vol. 26, pp 1874-1880, Geng et al. discloses poly(9,9-dihexylfluorene-alt-2,1,3-benzothiadiazole) (PFBT) loaded nanoparticles.

### SUMMARY

According to some embodiments of the present disclosure, there is provided a light-emitting composition comprising a light-emitting group and a polymer. The polymer contains an arylene repeat unit and a conjugation-breaking repeat unit.

Optionally, the arylene repeat unit has formula Ar¹ wherein Ar¹ is an arylene repeat unit which is unsubstituted or substituted with one or more substituents;

Optionally, the conjugation-breaking repeat unit is a repeat unit of formula (I):

[symbol]

Ar²-CB-Ar³ [symbol] (I)

wherein Ar² and Ar³ each independently represent a C₆₋₂₀ arylene group or a 5-20 membered heteroarylene group which is unsubstituted or substituted with one or more substituents and CB represents a conjugation-breaking group which does not provide a conjugation path between Ar² and Ar³.

Optionally, the polymer has a solubility in water or a C₁₋₈ alcohol at 20° C. of at least 0.1 mg/ml.

Optionally, CB contains at least one sp³ hybridised carbon atom separating Ar¹ and Ar².

Optionally, CB is a C₁₋₂₀ branched or linear alkylene group wherein one or more H atoms may be replaced with F and one or more non-adjacent C atoms of the alkylene group may be replaced with O, S, CO, COO or Si(R³)₂ wherein R³ in each occurrence is independently a C₁₋₂₀ hydrocarbyl group.

A hydrocarbyl group as described anywhere herein is optionally selected from C₁₋₂₀ alkyl; unsubstituted phenyl; and phenyl substituted with one or more C₁₋₂₀ alkyl groups

Optionally, Ar² and Ar³ are each independently selected from phenylene which is unsubstituted or substituted with one or more substituents; and fluorene of formula (IIb-1) as described below.

Optionally, at least one repeat unit of the polymer is substituted with at least one water or C₁₋₈ alcohol-solubilising substituent.

Optionally, the or each water or C₁₋₈ alcohol-solubilising substituent comprises an ionic group.

Optionally, Ar¹ is substituted with one or more water or C₁₋₈ alcohol-solubilising substituents.

In some embodiments, the light-emitting group is a light-emitting material mixed with the polymer.

In some embodiments, the polymer is a light-emitting polymer comprising the light-emitting group bound thereto. Optionally according to these embodiments, the light-emitting group is a light-emitting repeat unit of the light-emitting polymer.

In some embodiments, the light-emitting repeat unit comprises a heteroarylene group.

In some embodiments, the light-emitting repeat unit comprises an amine group.

In some embodiments, the light-emitting repeat unit comprises an arylene repeat unit substituted with the light-emitting group.

Optionally, Ar¹ is a C₆-C₁₄ arylene repeat unit.

Optionally, Ar¹ is a repeat unit of formula (II b-1):

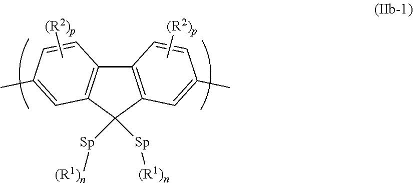

wherein Sp is a spacer group; R¹ in each occurrence is independently a polar group;
each n is independently at least 1; each R² is independently a non-polar substituent; and
p is 0 or a positive integer.

Optionally, at least one of Ar² and Ar³ is substituted with a group of formula -(Sp)m-(R¹)n wherein R¹ in each occurrence is independently a polar group selected from a non-ionic polar group and an ionic group; Sp is a spacer group; m is 0 or 1; n is 1 if m is 0; and n is at least 1 if m is 1. In some embodiments, the present disclosure provides a luminescent marker comprising the light-emitting composition described herein and a binding group configured to bind to a target material.

In some embodiments, the present disclosure provides a luminescent marker precursor comprising a light-emitting composition as described herein and a functional group. In some embodiments, the functional group is biotin.

In some embodiments, the present disclosure provides a method of forming a luminescent marker as described herein, the method comprising reacting a functional group of a luminescent marker precursor as described herein with a material for forming the binding group.

According to some embodiments of the present disclosure there is provided a solution containing the light-emitting composition dissolved in a solvent. The solvent may be selected from one or more of C₁₋₈ alcohols and water. Optionally, the solution may contain one or more other solvents in addition to one or more of C₁₋₈ alcohols and water. The solution may consist of the solvent or solvents and the light-emitting polymer or it may contain one or further materials dissolved or dispersed in the solution.

Optionally, the concentration of the polymer in the solution is at least: 0.1 mg/ml, 0.2 mg/ml, 0.5 mg/ml or 1 mg/ml.

According to some embodiments of the present disclosure there is provided a composite particle comprising a light-emitting composition according to any one of the preceding claims and a matrix material.

Optionally, the composite particle is substituted with a binding group configured to bind to a target material.

Optionally, the matrix material is silica.

Optionally, the composite particle comprises a binding group configured to bind to a target material.

In some embodiments there is provided a dispersion comprising composite particles as described herein dispersed in a liquid.

In some embodiments there is provided a method of detecting a target analyte in a sample, the method comprising contacting a luminescent marker as described herein substituted with a binding group or a composite particle as described herein with a sample.

Optionally, the sample comprising the light-emitting marker is irradiated with light at an absorption wavelength of the polymer and emission from the light-emitting marker is detected.

Optionally, target analyte bound to the light-emitting marker is separated from target analyte which is not bound to the light-emitting marker to give, respectively, first and second parts of the sample.

Optionally, the first part of the sample is irradiated with light at an absorption wavelength of the polymer.

Optionally, the first part of the sample is irradiated with at least two different wavelengths of light including the light at an absorption wavelength of the polymer.

### DESCRIPTION OF THE DRAWINGS

The disclosed technology and accompanying figures describe some implementations of the disclosed technology.

FIG. 1 is a graph of absorption spectra for two comparative light-emitting polymers and a light-emitting polymer according to some embodiments.

The drawings are not drawn to scale and have various viewpoints and perspectives. The drawings are some implementations and examples. Additionally, some components and/or operations may be separated into different blocks or combined into a single block for the purposes of discussion of some of the embodiments of the disclosed technology. Moreover, while the technology is amenable to various modifications and alternative forms, specific embodiments have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, electromagnetic, or a combination thereof. Additionally, the words “herein,” “above,” “below,” and words of similar import, when used in this application, refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list. References to an atom include any isotope of that atom unless stated otherwise.

The teachings of the technology provided herein can be applied to other systems, not necessarily the system described below. The elements and acts of the various examples described below can be combined to provide further implementations of the technology. Some alternative implementations of the technology may include not only additional elements to those implementations noted below, but also may include fewer elements.

These and other changes can be made to the technology in light of the following detailed description. While the description describes certain examples of the technology, and describes the best mode contemplated, no matter how detailed the description appears, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while some aspect of the technology may be recited as a computer-readable medium claim, other aspects may likewise be embodied as a computer-readable medium claim, or in other forms, such as being embodied in a means-plus-function claim.

In the following description, for the purposes of explanation, numerous specific details are set forth in order to provide a thorough understanding of implementations of the disclosed technology. It will be apparent, however, to one skilled in the art that embodiments of the disclosed technology may be practiced without some of these specific details.

A light-emitting composition as described herein contains a polymer and a light-emitting group.

By “composition” of a polymer and a light-emitting group is meant a polymer in which the light-emitting group is mixed with or bound to the polymer.

In some embodiments, the light-emitting group is a light-emitting material mixed with the polymer.

In some embodiments, the light-emitting group is bound to the polymer, e.g. covalently bound to the polymer. According to these embodiments, the polymer is a conjugated light-emitting polymer. A conjugated light-emitting polymer as described herein may contain an arylene host repeat unit; a light-emitting group; and conjugation-breaking repeat unit.

By “conjugated polymer”, e.g. a conjugated light-emitting polymer is meant a polymer having a backbone containing repeat units that are directly conjugated to adjacent repeat units in the polymer backbone. It will be appreciated that the polymer backbone is not conjugated along its entire length, due to interruptions in conjugation arising from at least the conjugation-breaking repeat unit.

In the case where the light-emitting group is bound to the polymer, the light-emitting group may be a repeat unit in the light-emitting polymer backbone; a light-emitting group pendant from the polymer backbone; or a light-emitting end-group of the polymer. In the case where the light-emitting group is pendant from the polymer backbone, it may be bound to an arylene repeat unit in the polymer backbone. The light-emitting group may be bound directly to the arylene repeat unit or spaced apart therefrom by a spacer group.

The light-emitting group may have a smaller HOMO-LUMO (highest occupied molecular orbital-lowest unoccupied molecular orbital) band gap than the arylene host repeat unit. In use, excitation energy (e.g. electromagnetic radiation) may be absorbed by the arylene host repeat units and transferred to the light-emitting group. A singlet exciton may be transferred to a fluorescent light-emitting group to produce fluorescent light. A triplet exciton may be transferred to a phosphorescent light-emitting group to produce phosphorescent light.

In the case where the light-emitting group is a light-emitting material mixed with the polymer, the polymer in isolation may be capable of emitting light. The polymer of such a mixture may emit some light (in addition to light emitted from the light-emitting material) or may emit no light.

In the case where a light-emitting material is mixed with the polymer in a particle, the close proximity of the polymer and the light-emitting material may facilitate transfer of energy from the polymer to the light-emitting material.

In the case where a light-emitting material and polymer are dissolved, there may be an electrostatic interaction between the light-emitting material and the polymer. Optionally, one or more of the repeat units of the polymer is substituted with one of an anionic substituent or a cationic substituent and the light-emitting material contains the other of an anionic and cationic substituent. Ionic substituents may be selected from ionic polar groups R¹ as described herein.

The polymer may have a solubility in water or a C₁₋₈ alcohol at 20° C. of at least 0.1 mg/ml, optionally at least 0.5 mg/ml or at least 1 mg/ml.

The polymer may have a solubility in a C₁₋₄ alcohol, preferably methanol, at 20° C. of at least 0.1 mg/ml, optionally at least 0.5 mg/ml or at least 1 mg/ml.

Solubility may be measured by the following method:

The solid polymer is weighed out into a glass vial. The required amount of polar solvent (for example methanol) is added followed by a small magnetic stirrer. Then the vial is tightly capped and put on a preheated hot plate at 60° C. with stirring for 30 min. The polymer solution is allowed to cool to room temperature before use. The polymer solution can also be prepared by sonicating the polymer containing vial for 30 min at room temperature. The solubility of polymer was tested by visual observation and under white and 365 nm UV light.

The present inventors have found that introducing a conjugation-breaking repeat unit into a conjugated polymer may prevent formation of broad absorption peaks e.g. absorption peaks arising from conjugation of host arylene repeat units in the polymer backbone to one another. This may allow excitation of the polymer at two or more different wavelengths no more than 100 nm apart with significantly different emission intensities.

Optionally, the polymer has an absorption peak with a full width at half maximum (FWHM) of less than 100 nm.

The present inventors have found that the solubility of the polymer may be adjusted by selection of one or both of substituents of the polymer and conjugation-breaking groups of the polymer. Polymers which are soluble in polar solvents as described herein may be used in, e.g.:
polymerisation of a silane in the presence of the light-emitting composition in a polar solvent, such as by the \ddot{S}tober process, to form particles containing silica and the light-emitting composition; and/or
an assay in a polar solvent using the light-emitting composition as a fluorescent tag.

One or more repeat units of the polymer may be substituted with one or more water or C₁₋₈ alcohol-solubilising substituents. A water or C₁₋₈ alcohol solubilising substituent as described herein may enhance solubility of the polymer as compared to a polymer in which the water or C₁₋₈ alcohol solubilising substituent is not present, e.g. in which the water or C₁₋₈ alcohol solubilising substituent is replaced with H or a non-polar substituent such as an alkyl substituent.

The water or C₁₋₈ alcohol solubilising substituent may consist of a polar group or may comprise one or more polar groups. Polar groups are preferably non-ionic groups capable of forming hydrogen bonds or ionic groups.

The polymers described herein may be random, block or regioregular copolymers.

Conjugated polymers as described herein may be formed by polymerising monomers comprising leaving groups that leave upon polymerisation of the monomers to form conjugated repeat units. Exemplary polymerization methods include, without limitation, Yamamoto polymerization as described in, for example, T. Yamamoto, “Electrically Conducting And Thermally Stable pi-Conjugated Poly(arylene)s Prepared by Organometallic Processes”, Progress in Polymer Science 1993, 17, 1153-1205, the contents of which are incorporated herein by reference and Suzuki polymerization as described in, for example, WO 00/53656, WO 2003/035796, and U.S. Pat. No. 5,777,070, the contents of which are incorporated herein by reference.

The monomers may be formed by polymerisation of monomers containing boronic acid leaving groups or esters thereof, and halide or pseudohalide (e.g. sulfonate) leaving groups. Leaving groups may be selected to control which monomers may or may not form adjacent repeat units in the polymer. Optionally, no arylene repeat units are adjacent to one another in the polymer.

The polystyrene-equivalent number-average molecular weight (Mn) measured by gel permeation chromatography of the polymers described herein, preferably the polymers described herein may be in the range of about 1×10³ to 1×10⁸, and preferably 1×10⁴ to 5×10⁶. The polystyrene-equivalent weight-average molecular weight (Mw) of the polymers described herein may be 1×10³ to 1×10⁸, and preferably 1×10⁴ to 1×10⁷.

Arylene Host Repeat Unit

The arylene host repeat Ar¹ may be a C₆-C₁₄ arylene repeat unit, for example a repeat unit selected from phenylene, fluorene, benzofluorene, phenanthrene, dihydrophenanthrene, naphthalene or anthracene.

The polymer may contain only one Ar¹ repeat unit. The polymer may contain two or more different Ar¹ repeat units.

The one or more arylene repeat units Ar¹ may make up at least 40 mol % at least 40 mol % of the repeat units of the polymer, optionally 40-80 mol % of the repeat units of the polymer.

The, or each, Ar¹ repeat unit may be unsubstituted or substituted. Substituents may be selected from polar and non-polar substituents. In some preferred embodiments, Ar¹ is substituted with one or more polar substituents, optionally one or more ionic substituents.

Optionally, the polymer comprises a repeat unit of formula (II):

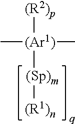

wherein Ar¹ is an arylene group, e.g. a C₆₋₁₄ arylene group; Sp is a spacer group; m is 0 or 1; R¹ independently in each occurrence is a polar group; n is 1 if m is 0 and n is at least 1, optionally 1, 2, 3 or 4, if m is 1; R² independently in each occurrence is a non-polar group; p is 0 or a positive integer; q is at least 1, optionally 1, 2, 3 or 4; and wherein Sp, R¹ and R² may independently in each occurrence be the same or different.

In some embodiments, q is 1 or 2. Preferably, m is 1 and n is 1-4.

Preferably p is 0.

Preferably, Sp is selected from:
C₁₋₂₀ alkylene or phenylene-C₁₋₂₀ alkylene wherein one or more non-adjacent C atoms may be replace with O, S, N or C═O;
a C₆₋₂₀ arylene or 5-20 membered heteroarylene, more preferably phenylene, which, other than the one or more polar groups R¹, may be unsubstituted or substituted with one or more non-polar substituents, optionally one or more C₁₋₂₀ alkyl groups.

More preferably, Sp is selected from:
C₁₋₂₀ alkylene wherein one or more non-adjacent C atoms may be replaced with O, S or CO; and
a C₆₋₂₀ arylene or a 5-20 membered heteroarylene, even more preferably phenylene, which may be unsubstituted or substituted with one or more non-polar substituents.

R¹ may be an ionic group or a non-ionic polar group.

An exemplary non-ionic polar group has formula —O(R³O)ᵥ—R⁴ wherein R³ in each occurrence is a C₁₋₁₀ alkylene group, optionally a C₁₋₅ alkylene group, wherein one or more non-adjacent, non-terminal C atoms of the alkylene group may be replaced with O, R⁴ is H or C₁₋₅ alkyl, and v is 0 or a positive integer, optionally 1-10. Preferably, v is at least 2. More preferably, v is 2 to 5. The value of v may be the same in all the polar groups of formula —O(R³O)ᵥ—R⁴. The value of v may differ between polar groups of the same polymer.

Optionally, the non-ionic polar group has formula O(CH₂CH₂O)ᵥR⁴ wherein v is at least 1, optionally 1-10 and R⁴ is a C₁₋₅ alkyl group, preferably methyl. Preferably, v is at least 2. More preferably, v is 2 to 5, most preferably v is 3.

By “C₁₋₁₀ alkylene group” as used herein with respect to R³ is meant a group of formula —(CH₂)_{f}— wherein f is from 1-10.

By “non-terminal C atom” of an alkyl group as used herein means a C atom other than the methyl group at the end of an n-alkyl group or the methyl groups at the ends of a branched alkyl chain.

In some embodiments, one or more repeat units of the polymer are substituted with a substituent consisting of an ionic group or comprising one or more ionic groups. Ionic groups may be anionic, cationic or zwitterionic. Preferably the ionic group is an anionic group.

Exemplary anionic group are —COO⁻, a sulfonate group; hydroxide; sulfate; phosphate; phosphinate; or phosphonate.

An exemplary cationic group is —N(R⁵)₃⁺ wherein R⁵ in each occurrence is H or C₁₋₁₂ hydrocarbyl. Preferably, each R⁵ is a C₁₋₁₂ hydrocarbyl.

Cationic substituents may interact electrostatically with a target comprising one or more anionic groups, e.g. polysaccharides, polynucleotides, peptides and proteins carrying one or more anionic groups.

A polymer comprising cationic or anionic groups comprises counterions to balance the charge of these ionic groups.

An anionic or cationic group and counterion may have the same valency, with a counterion balancing the charge of each anionic or cationic group.

The anionic or cationic group may be monovalent or polyvalent. Preferably, the anionic and cationic groups are monovalent.

The polymer may comprise a plurality of anionic or cationic polar groups wherein the charge of two or more anionic or cationic groups is balanced by a single counterion. Optionally, the polar groups comprise anionic or cationic groups comprising di- or trivalent counterions.

In the case of an anionic group, the cation counterion is optionally a metal cation, optionally Li⁺, Na⁺, K⁺, Cs⁺, preferably Cs⁺, or an organic cation, optionally ammonium, such as tetraalkylammonium, ethylmethyl imidazolium or pyridinium.

In the case of a cationic group, the anion counterion is optionally a halide; a sulfonate group, optionally mesylate or tosylate; hydroxide; carboxylate; sulfate; phosphate; phosphinate; phosphonate; or borate.

In some embodiments, the polymer comprises polar groups selected from groups of formula —O(R³O)ᵥ—R⁴ and/or ionic groups. Preferably, the polymer comprises polar groups selected from groups of formula —O(CH₂CH₂O)ᵥR⁴ and/or anionic groups of formula —COO⁻.

R¹ may be a polar group as described anywhere herein. Preferably, R¹ in each occurrence is independently selected from the group consisting of:

Preferably, at least one R¹ is —COO⁻.

In the case where n is at least 2, each R¹ may independently in each occurrence be the same or different. In some embodiments where n is at least 2 each R¹ is different.

In the case where p is a positive integer, optionally 1, 2, 3 or 4, the group R² may be selected from:
alkyl, optionally C₁₋₂₀ alkyl; and
aryl and heteroaryl groups that may be unsubstituted or substituted with one or more substituents, preferably phenyl substituted with one or more C₁₋₂₀ alkyl groups;
a linear or branched chain of aryl or heteroaryl groups, each of which groups may independently be substituted, for example a group of formula -(Ar³), wherein each Ar³ is independently an aryl or heteroaryl group and s is at least 2, preferably a branched or linear chain of phenyl groups each of which may be unsubstituted or substituted with one or more C₁₋₂₀ alkyl groups; and
a crosslinkable-group, for example a group comprising a double bond such and a vinyl or acrylate group, or a benzocyclobutane group.

Two R² groups may be linked to form a ring, e.g. a 6-membered ring or 7-membered ring. Optionally, two R² groups are linked to form a ring in which the linked R2 groups form a C₄- or C₅-alkylene chain wherein one or more non-adjacent C atoms of the alkylene chain may be replaced with O, S, NR¹⁰ or Si(R¹⁰)₂ wherein R¹⁰ in each occurrence is independently a C₁₋₂₀ hydrocarbyl group.

Preferably, each R², where present, is independently selected from C₁₋₄₀ hydrocarbyl, and is more preferably selected from C₁₋₂₀ alkyl; unsubstituted phenyl; phenyl substituted with one or more C₁₋₂₀ alkyl groups; and a linear or branched chain of phenyl groups, wherein each phenyl may be unsubstituted or substituted with one or more substituents; or two R² groups are linked to form a ring as described herein

Optionally, repeat units of formula (II) are selected from formulae (IIa)-(IId):

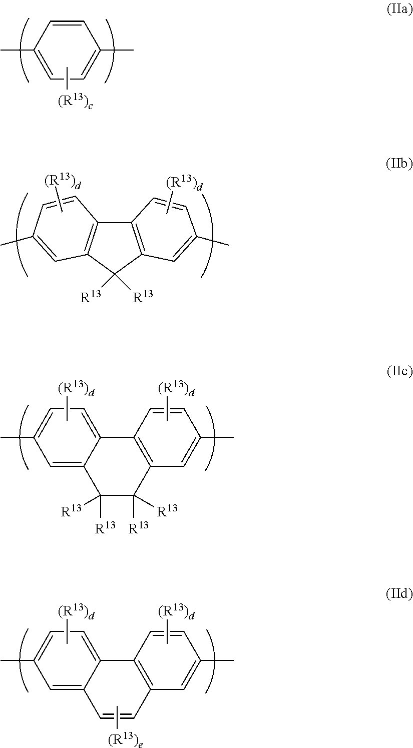

wherein R¹³ in each occurrence is independently -(Sp)ₘ-(R¹)ₙ or R² and two R¹³ groups may be linked to form a ring, with the proviso that at least one R¹³ is -(Sp)ₘ-(R¹)ₙ; c is 0, 1, 2, 3 or 4, preferably 1 or 2; each d is independently 0, 1, 2 or 3, preferably 0 or 1; and e is 0, 1 or 2, preferably 2.

In some preferred embodiments, the repeat unit of formula (IIb) is a repeat unit of formula (IIb-1):

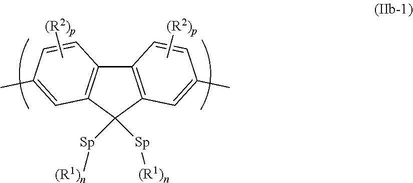

wherein R², p, Sp, R¹ and n are independently in each occurrence as described above. In some preferred embodiments, n in each occurrence is 2. In some preferred embodiments, p in each occurrence is 0.

An exemplary repeat unit of formula (IIb-1) is:

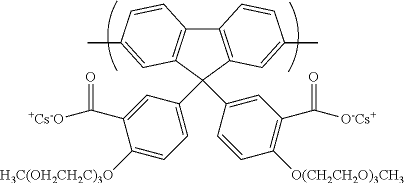

In some preferred embodiments, the polymer contains a repeat unit of formula (I) and a repeat unit of formula (II) wherein each of the repeat units of formulae (I) and (II) is substituted with at least one substituent of formula -(Sp)ₘ-(R¹)ₙ.

Conjugation-Breaking Repeat Unit

The conjugation-breaking repeat unit may have formula (I):

[symbol]

Ar²-CB-Ar³ [symbol] (I)

wherein Ar² and Ar³ each independently represent a C₆₋₂₀ arylene group or a 5-20 membered heteroarylene group which is unsubstituted or substituted with one or more substituents; CB represents a conjugation-breaking group which does not provide a conjugation path between Ar² and Ar³.

Optionally, the repeat unit of formula (I) makes up 1-50 mol %, optionally 1-25 mol %, of the repeat units of the polymer.

Ar² and Ar³ are each independently unsubstituted or substituted with one or more substituents. Substituents of Ar² and Ar³, where present, are optionally selected from -(Sp)ₘ*(R¹)ₙ or R² as described above.

In a preferred embodiment, at least one of Ar² and Ar³ is substituted with at least one substituent -(Sp)ₘ-(R¹)ₙ.

Optionally, Ar² and Ar³ are each independently unsubstituted or substituted phenylene, optionally 1,3- or 1,4-linked phenylene.

CB does not provide any conjugation path between Ar² and Ar³. Optionally, CB does not provide a path of alternating single and double bonds between Ar¹ and Ar².

Optionally, CB is a C₁₋₂₀ branched or linear alkylene group wherein one or more H atoms may be replaced with F and one or more non-adjacent C atoms of the alkylene group may be replaced with O, S, CO, COO or Si(R¹⁰)₂ wherein R¹⁰ in each occurrence is independently a C₁₋₂₀ hydrocarbyl group.

Optionally, CB contains least one sp³ hybridised carbon atom separating Ar¹ and Ar².

The conjugation-breaking repeat unit may have formula (Ia) or (Ib):

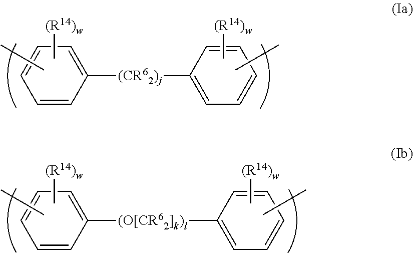

wherein R¹⁴ in each occurrence is independently selected from -(Sp)ₘ-(R¹)ₙ or R² as described above; each w is independently 0-4, optionally 0, 1 or 2; each R⁶ is independently H or a C₁₋₆ alkyl group, preferably H; j is at least 1; k is at least 1; and 1 is at least 1.

In some embodiments, each w is 0.

In some embodiments, at least one w is 1 or 2.

R¹⁴, where present, is preferably a C₁₋₁₂ alkyl group.

Optionally, j is 2-20 or 2-12.

Optionally, k is 2-6, preferably 2.

Optionally, 1 is 1-6.

Exemplary repeat units of formulae (Ia) and (Ib) are:

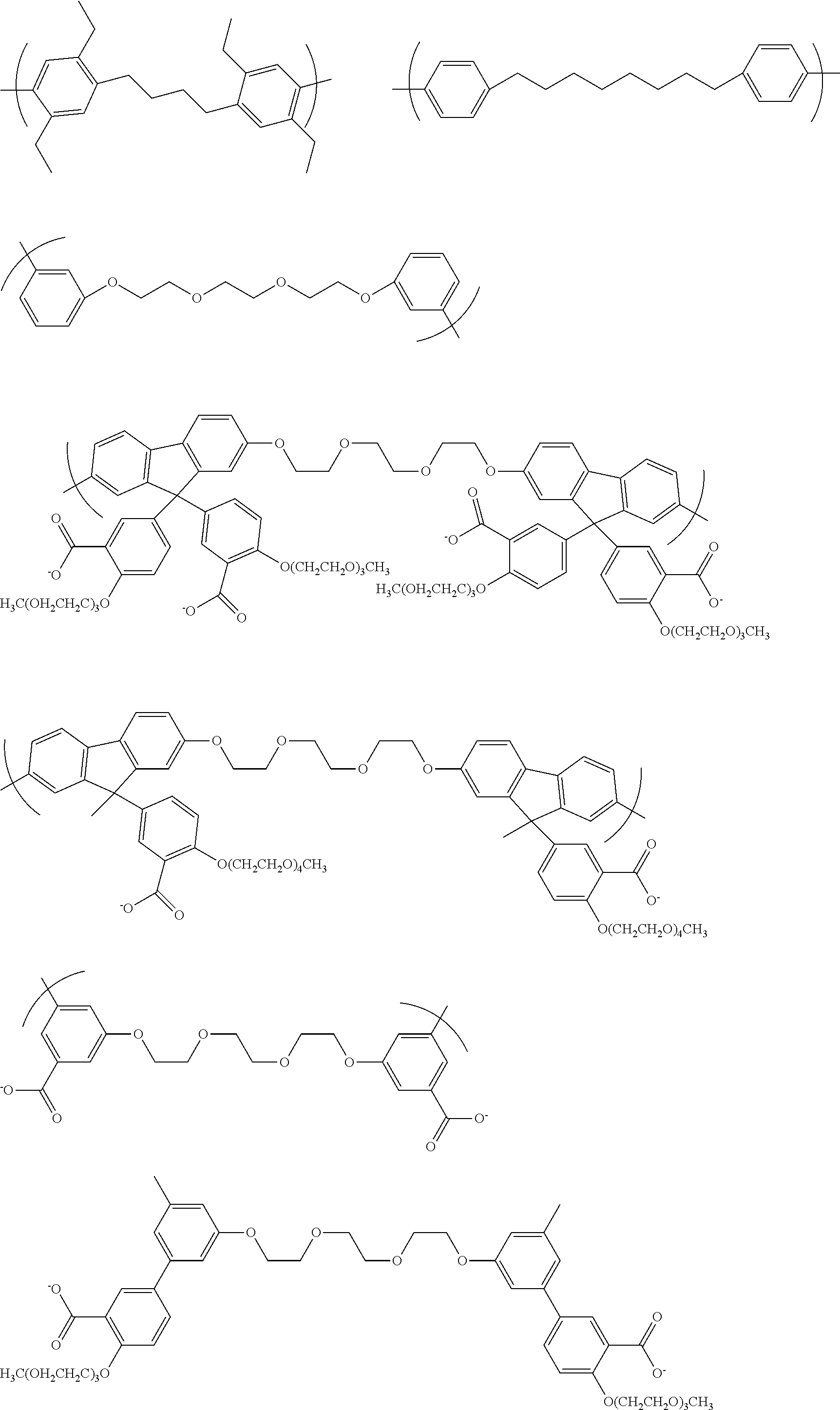

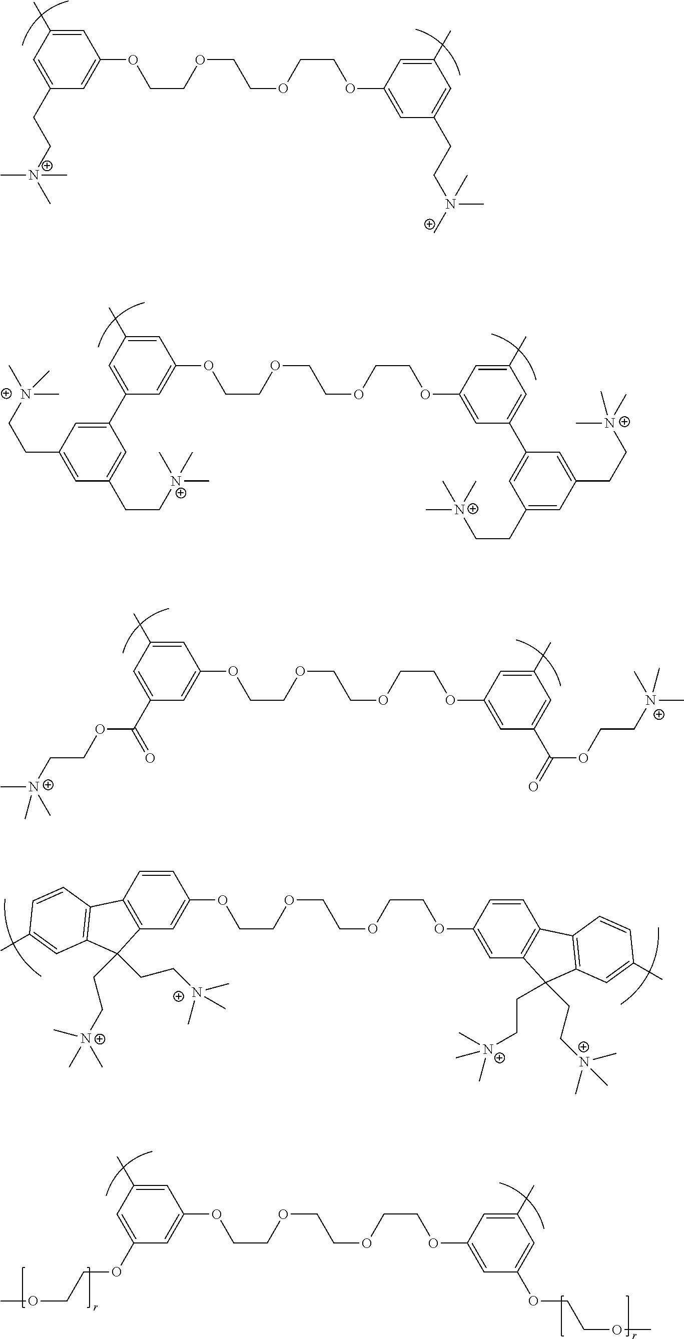

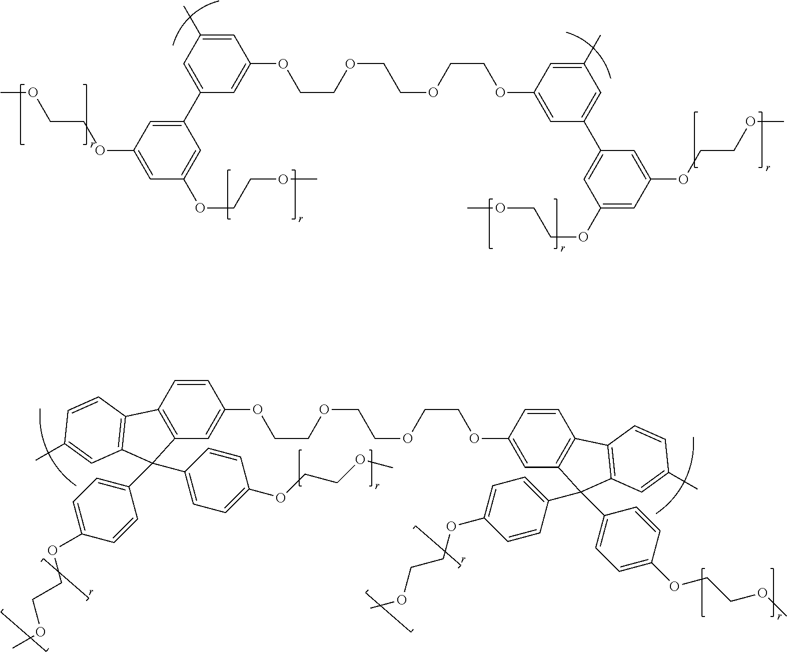

wherein r independently in each occurrence is at least 1, optionally 1-10.

It will be understood that repeat units substituted with one or more anionic or cationic groups will be associated with a cation or anion counterion as described herein.

In some embodiments, formation of a repeat unit of formula (I) substituted with an ionic group comprises polymerisation of a monomer comprising a non-ionic precursor group followed by conversion of the non-ionic precursor group to the ionic group.

The conversion may be conversion of a carboxylic ester precursor group to a carboxylate ionic group. This conversion may be as described in WO 2012/133229, the contents of which are incorporated herein by reference.

The conversion may be conversion of a tertiary amine to a quaternary amine, e.g. by reaction with an alkyl halide such as methyl iodide.

Light-Emitting Groups

The, or each, light-emitting group of a light-emitting polymer as described herein, or light-emitting group mixed with a polymer as described herein, may have a smaller HOMO-LUMO band gap than any of the one or more host arylene repeat units.

The bandgap of a host arylene repeat unit may be the bandgap of a monomer for forming the host repeat unit. In the case where the light-emitting group is bound to the polymer, the bandgap of the light-emitting group may be the bandgap of a monomer or end-forming group for forming, respectively, a light-emitting repeat unit or an end group comprising the light-emitting group.

HOMO and LUMO levels as described herein may be as determined by square wave voltammetry.

The, or each, light-emitting group of the polymer or light-emitting group mixed with the polymer may be selected to produce a desired colour of emission of the polymer.

A blue light-emitting composition, e.g. a blue light-emitting polymer may have a photoluminescence spectrum with a peak of no more than 500 nm, preferably in the range of 400-500 nm, optionally 400-490 nm.

A green light-emitting composition, e.g. a blue light-emitting may have a photoluminescence spectrum with a peak of more than 500 nm up to 580 nm, optionally more than 500 nm up to 540 nm.

A red light-emitting composition, e.g. a blue light-emitting may have a photoluminescence spectrum with a peak of no more than more than 580 nm up to 630 nm, optionally 585 nm up to 625 nm.

It will be understood that conjugation of a light-emitting repeat unit to adjacent repeat units may result in a change in emission from the polymer as compared to emission from a corresponding monomer.

The photoluminescence spectrum of light-emitting materials or compositions as described herein may be as measured using an Ocean Optics 2000+ spectrometer.

Mechanisms for energy transfer include, for example, resonant energy transfer; Forster (or fluorescence) resonance energy transfer (FRET), quantum charge exchange (Dexter energy transfer) and the like.

In the case of a light-emitting material mixed with the polymer, the light-emitting material may be a non-polymeric light-emitting material.

Exemplary non-polymeric light-emitting materials include, without limitation, fluoresceins and salts thereof including, without limitation, fluorescein and fluorescein isothiocyanate (FITC); rhodamines, for example Rhodamine 6G and Rhodamine 110 chloride; coumarins; boron-dipyrromethenes (BODIPYs); naphthalimides; perylenes; benzanthrones; benzoxanthrones; and benzothiooxanthrones, each of which may be unsubstituted or substituted with one or more substituents. Exemplary substituents are chlorine, alkyl amino; phenylamino; and hydroxyphenyl.

In the case of a light-emitting polymer, one or more light-emitting repeat units may make up at least 1 mol % of the repeat units of the light-emitting polymer, optionally at least 3 mol %, optionally 3-45 mol % of the repeat units of the light-emitting polymer.

Exemplary light-emitting repeat units include, without limitation, repeat units comprising a heteroarylene group or an amine group in the backbone of the polymer; and an arylene group in the backbone of the polymer substituted with a light-emitting group pendant from the polymer backbone. The light-emitting group may be bound directly to the arylene group or spaced apart from the arylene group by a spacer group.

An exemplary spacer group is a C₁₋₂₀ alkylene wherein one or more non-adjacent C atoms may be replaced with O, S, CO, COO, NR¹⁰, Si(R¹⁰)₂ and phenylene wherein R¹⁰ in each occurrence is independently a C₁₋₂₀ hydrocarbyl group. An arylene repeat unit substituted with a light-emitting group may be a group of formula (II) wherein at least one R² is a light-emitting group bound directly to Ar1 or spaced apart therefrom by a spacer group. The light-emitting group may be a non-polymeric light-emitting material as described above.

The light-emitting repeat units may be unsubstituted or substituted with one or more substituents, e.g. one or more C₁₋₂₀ alkyl groups.

Repeat units comprising or consisting of one or more unsubstituted or substituted 5-20 membered heteroarylene groups in the polymer backbone include, without limitation, thiophene repeat units, bithiophene repeat units, benzothiadiazole repeat units, and combinations thereof. Exemplary heteroarylene co-repeat units include repeat units of formulae (VII), (VIII) and (IX):

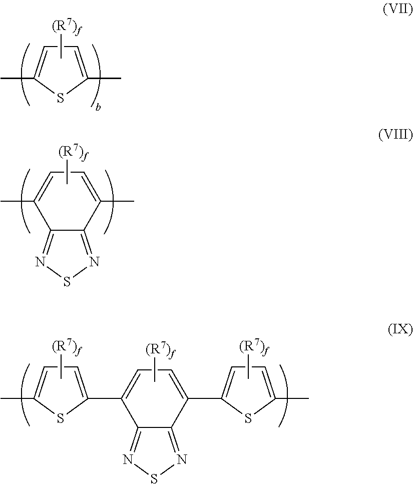

wherein R⁷ in each occurrence is independently a substituent; b is 1 or 2; and f is 0, 1 or 2.

Where present, each R⁷ is optionally and independently selected from the group consisting of:

C₁₋₂₀ alkyl wherein one or more non-adjacent, non-terminal C atoms may be replaced with O, S, CO or COO and one or more H atoms may be replaced with F;

phenyl which may be unsubstituted or substituted with one or more substituents, optionally one or more of F, CN, NO2 and C₁₋₁₂ alkyl wherein one or more non-adjacent, non-terminal C atoms may be replaced with O, S, CO or COO and one or more H atoms may be replaced with F; and

-(Sp)ₘ-(R¹)ₙ.

Preferably, each R⁷, where present, is a hydrocarbyl group, e.g. a C₁₋₂₀ alkyl. Substituting the light-emitting repeat unit with a polar substituent, e.g. a group of formula -(Sp)ₘ-(R¹)ₙ, may result in a change in the emission and/or absorption characteristics of the light-emitting polymer.

Light-emitting amine repeat units may have formula (XII):

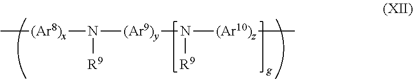

wherein Ar⁸, Ar⁹ and Ar¹⁰ in each occurrence are independently selected from substituted or unsubstituted aryl or heteroaryl, g is 0, 1 or 2, preferably 0 or 1, R⁹ independently in each occurrence is a substituent, and x, y and z are each independently 1, 2 or 3.

R⁹, which may be the same or different in each occurrence when g is 1 or 2, is preferably selected from the group consisting of alkyl, optionally C₁₋₂₀ alkyl, Ar¹¹ and a branched or linear chain of Ar¹¹ groups wherein Ar¹¹ in each occurrence is independently substituted or unsubstituted aryl or heteroaryl.

Any two aromatic or heteroaromatic groups selected from Ar⁸, Ar⁹, and, if present, Ar^{m} and Ar¹¹ that are directly bound to the same N atom may be linked by a direct bond or a divalent linking atom or group. Preferred divalent linking atoms and groups include O, S; substituted N; and substituted C.

Ar⁸ and Ar¹⁰ are preferably C₆₋₂₀ aryl, more preferably phenyl, which may be unsubstituted or substituted with one or more substituents.

In the case where g=0, Ar⁹ is preferably C₆₋₂₀ aryl, more preferably phenyl, that may be unsubstituted or substituted with one or more substituents.

In the case where g=1, Ar⁹ is preferably C₆₋₂₀ aryl, more preferably phenyl or a polycyclic aromatic group, for example naphthalene, perylene, anthracene or fluorene, that may be unsubstituted or substituted with one or more substituents.

R⁹ is preferably Ar¹¹ or a branched or linear chain of Ar¹¹ groups. Ar¹¹ in each occurrence is preferably phenyl that may be unsubstituted or substituted with one or more substituents.

Exemplary groups R⁹ include the following, each of which may be unsubstituted or substituted with one or more substituents, and wherein * represents a point of attachment to N:

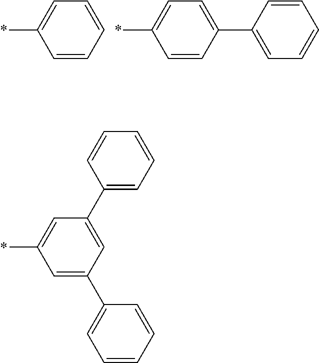

x, y and z are preferably each 1.

Ar⁸, Ar⁹, and, if present, Ar¹⁰ and Ar¹¹ are each independently unsubstituted or substituted with one or more, optionally 1, 2, 3 or 4, substituents.

Substituents may independently be a group comprising or consisting of a polar group, optionally a polar substituent -(Sp)ₘ-(R¹)ₙ, or a non-polar substituent R² wherein Sp, m, R¹ and R² are as described above.

Preferred substituents of Ar⁸, Ar⁹, and, if present, Ar¹⁰ and Ar¹¹ are C₁₋₄₀ hydrocarbyl, preferably C₁₋₂₀ alkyl.

Preferred repeat units of formula (XII) include unsubstituted or substituted units of formulae (XII-1), (XII-2) and (XII-3):

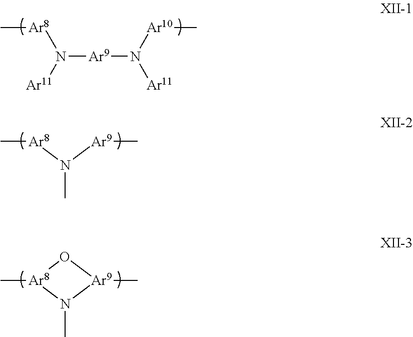

In the case of a phosphorescent conjugated polymer a phosphorescent group, preferably a metal complex, more preferably an iridium complex, may be provided in the main chain, in a side group and/or as an end group of the polymer. An exemplary conjugating repeat unit comprising an iridium complex has formula:

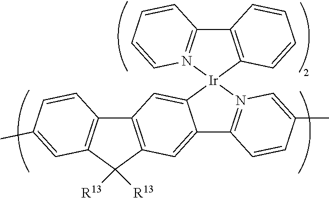

Luminescent Marker

A luminescent marker may comprise a light-emitting composition as described herein, preferably a light-emitting polymer, and a binding group, preferably a biomolecule binding group, configured to bind to a target analyte.

In some embodiments, the binding group is bound, preferably covalently bound, to the polymer. The binding group may be provided as a side group of a repeat unit of the polymer or as an end-group of the polymer.

In some embodiments, the luminescent marker is dissolved in a sample to be analysed.

In some embodiments, the luminescent marker is a particulate luminescent marker.

Formation of a luminescent nanoparticle marker may comprise collapse of a light-emitting polymer. A light-emitting particle may comprise a light-emitting composition, e.g. a light-emitting polymer or a mixture of a polymer and a light-emitting material as described herein and a matrix. The matrix may at least partially isolate the light-emitting material from the surrounding environment. This may limit any effect that the external environment may have on the lifetime of the light-emitting material.

In some embodiments, the particle comprises the light-emitting composition, e.g. the light-emitting polymer, homogenously distributed through the matrix.

In some embodiments, the particle may have a particulate core and, optionally, a shell wherein at least one of the core and shell contains the light-emitting composition. Preferably, the light-emitting particle contains the light-emitting composition and a matrix material.

Polymer chains of the polymer may extend across some or all of the thickness of the core and/or shell. Polymer chains may be contained within the core and/or shell or may protrude through the surface of the core and/or shell.

In some embodiments, the particle comprises a core comprising or consisting of the light-emitting composition and a shell comprising or consisting of the matrix.

The matrix may be inorganic. The inorganic matrix may be an oxide, optionally silica, alumina or titanium dioxide.

Preferably, the matrix is not covalently bound to the polymer. Accordingly, there is no need for the matrix material and/or the polymer to be substituted with reactive groups for forming such covalent bonds, e.g. during formation of the particles.

In some embodiments, a silica matrix as described herein may be formed by polymerisation of a silica monomer in the presence of the light-emitting composition.

In some embodiments, the polymerisation comprises bringing a solution of silica monomer into contact with an acid or a base. The acid or base may be in solution. The light-emitting composition may be in solution with the acid or base and/or the silica monomer before the solutions are mixed. Optionally, the solvents of the solutions are selected from water, one or more C₁₋₈ alcohols or a combination thereof.

Polymerising a matrix monomer in the presence of a polymer may result in one or more chains of the polymer encapsulated within the particle and/or one or more chains of the polymer extending through a particle.

The particles may be formed in a one-step polymerisation process.

Optionally, the silica monomer is an alkoxysilane, preferably a trialkoxy or tetra-alkoxysilane, optionally a C₁₋₁₂ trialkoxy or tetra-alkoxysilane, for example tetraethyl orthosilicate. The silica monomer may be substituted only with alkoxy groups or may be substituted with one or more groups.

In some embodiments, a luminescent marker as described herein comprises a biomolecule binding group is bound to a surface of a light-emitting particle. The biomolecule binding group may be bound directly to the surface of the particle group or bound through a surface binding group. The surface binding group may comprise polar groups. Optionally, the surface binding group comprises a polyether chain. By “polyether chain” as used herein is meant a chain having two or more ether oxygen atoms.

Silica at the surface of the particles may be reacted to form a group at the surface capable of binding to a biomolecule binding group. Optionally, silica at the surface is reacted with a siloxane.

The biomolecule binding group of a soluble or a particulate light-emitting marker as described herein may be selected from the group consisting of: DNA, RNA, peptides, carbohydrates, antibodies, antigens, enzymes, proteins and hormones. The biomolecule binding group may be selected according to a target biomolecule to be detected.

Target biomolecules include without limitation DNA, RNA, peptides, carbohydrates, antibodies, antigens, enzymes, proteins and hormones. It will be understood that the biomolecule binding group may be selected according to the target biomolecule or binding agent.

The binding group of the light-emitting marker for binding to a target analyte may be attached to a functional group of a precursor of the light-emitting marker comprising the light-emitting composition. In some embodiments, the functional group is covalently bound to the polymer. In some embodiments, the functional group is covalently bound to a matrix material of a precursor comprising the matrix material and the light-emitting composition.

Optionally the functional group is selected from:

amine groups, optionally —NR¹¹₂ wherein R¹¹ in each occurrence is independently H or a substituent, preferably H or a C₁₋₅ alkyl, more preferably H;
carboxylic acid or a derivative thereof, for example an anhydride, acid chloride or ester, acid chloride, acid anhydride or amide group;
—OH; —SH; an alkene; an alkyne; and an azide; and
biotin or a biotin-protein conjugate.

The functional group may be reacted with or conjugated to a biomolecule to form a linking group linking the biomolecule to the rest of the light-emitting marker, the linking group being selected from esters, amides, urea, thiourea, Schiff bases, a primary amine (C—N) bond, a maleimide-thiol adduct or a triazole formed by the cycloaddition of an azide and an alkyne.

In the case where the functional group is biotin, it may be conjugated to a protein, e.g. avidin, streptavidin, neutravidin and recombinant variants thereof, and a biotinylated biomolecule may be conjugated to the protein to form the light-emitting marker.

The biotinylated biomolecule may comprise an antigen binding fragment, e.g. an antibody, which may be selected according to a target antigen.

In the case of a light-emitting particle, the functional group may be bound to a surface of the particle core, e.g. bound to a matrix material of the light-emitting particle core. Each functional group may be directly bound to the surface of a light-emitting particle core or may be spaced apart therefrom by one or more surface binding groups. The surface binding group may comprise polar groups. Optionally, the surface binding group comprises a polyether chain.

The surface of a light-emitting particle core may be reacted to form a group at the surface capable of attaching to a functional group. Optionally, a silica-containing particle is reacted with a siloxane.

Preferably, particulate luminescent markers or particulate luminescent marker precursors as described herein have a number average diameter of no more than 5000 nm, more preferably no more than 2500 nm, 1000 nm, 900 nm, 800 nm, 700 nm, 600 nm, 500 nm or 400 nm as measured by dynamic light scattering (DLS) using a Malvern Zetasizer Nano ZS. Preferably the particles have a number average diameter of between 5-5000 nm, optionally 10-1000 nm, preferably between 10-500 nm, most preferably between 10-100 nm as measured by a Malvern Zetasizer Nano ZS.

Preferably, at least 50 wt % of the total weight of the particulate luminescent marker precursor consists of matrix material. Preferably at least 60, 70, 80, 90, 95, 98, 99, 99.5, 99.9 wt % of the total weight of the particle consists of matrix material.

The particulate luminescent markers or particulate luminescent marker precursors as described herein may be provided as a colloidal suspension comprising the particles suspended in a liquid. Preferably, the liquid is selected from water, C₁₋₈ alcohols and mixtures thereof. Preferably, the particles form a uniform (non-aggregated) colloid in the liquid.

The liquid may be a solution comprising salts dissolved therein, optionally a buffer solution.

Applications

Luminescent markers comprising light-emitting compositions as described herein may be used as luminescent probes in an immunoassay such as a lateral flow or solid state immunoassay. Optionally the luminescent markers are for use in fluorescence microscopy or flow cytometry. Optionally the luminescent markers are for use in fluorescence microscopy, flow cytometry, next generation sequencing, in-vivo imaging, or any other application where a light-emitting marker is brought into contact with a sample to be analysed. The analysis may be performed using time-resolved spectroscopy. The applications can medical, veterinary, agricultural or environmental applications whether involving patients (where applicable) or for research purposes.

Optionally, in use the light-emitting composition is irradiated by light of two or more different wavelengths, e.g. wavelengths including at least two of 355, 405, 488, 530, 562 and 640 nm±10 nm. By use of polymers having well-defined absorption bands, absorptions at different wavelengths are readily distinguishable from one another.

In some embodiments, dissolved light-emitting composition is brought into contact with a sample to be analysed.

In some embodiments, particles containing the light-emitting composition, for example the particles in a colloidal suspension, are brought into contact with a sample to be analysed. The particles may comprise a matrix and the light-emitting composition as described herein. A target analyte may be immobilised on a surface carrying a group capable of binding to the target analyte, either before or after the target analyte binds to a component of the dissolved light-emitting composition, e.g. a light-emitting polymer, or to particles containing the light-emitting polymer. The target analyte bound to the light-emitting polymer, or one of a polymer or a light-emitting group mixed with the polymer, may then be separated from any light-emitting composition which is not bound to the target analyte.

In some embodiments, the particles may be stored in a dry, optionally lyophilised, form.

### EXAMPLES

Monomer Example 1 was prepared according to the following reaction scheme:

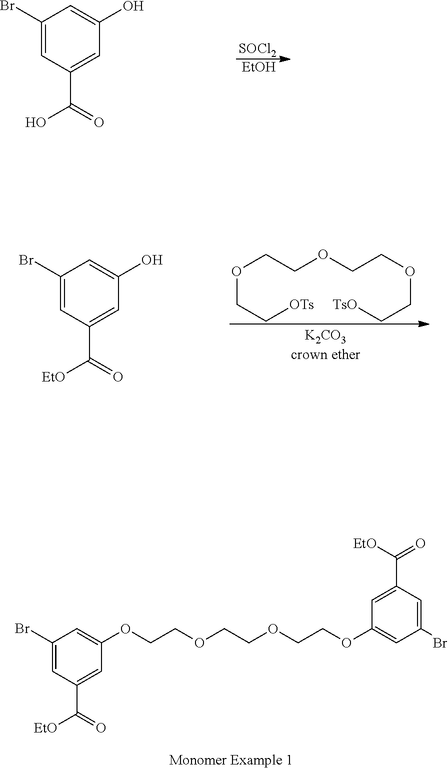 [SMILES: "EtOH" ; O=C(O)c1cc(O)cc(Br)c1 ; "SOCl2" ; CCOC(=O)c1cc(O)cc(Br)c1 ; Cc1ccc(S(=O)(=O)OCCOCCOCCOCCOS(=O)(=O)c2ccc(C)cc2)cc1 ; CCOC(=O)c1cc(Br)cc(OCCOCCOCCOc2cc(Br)cc(C(=O)OCC)c2)c1]

Stage 1

3-Bromo-5-hydroxybenzoic acid (50 g, 230 mmol) was suspended in ethanol (500 mL). The stirred reaction mixture was cooled in an ice bath before thionyl chloride (34.1 mL, 460 mmol) was added dropwise over 15 mins. The reaction mixture was stirred and allowed to warm to room temperature overnight. The solvent was removed and the yellow crude product was purified by column chromatography on silica eluting with ethyl acetate in hexanes. The product-containing fractions were combined and concentrated to give stage 1 material (40 g, 71%) with 99% HPLC purity.

### Monomer Example 1

Stage 1 material (40 g, 163 mmol) and tetraethylene glycol ditosylate (25 g, 54.5 mmol) were dissolved in DMF (400 mL). Potassium carbonate (45.0 g, 326 mmol) and 18-vrown ether (1.43 g, 5.43 mmol) were added and the mixture was stirred at 110° C. overnight. The reaction was poured onto ice and the organics extracted with ethyl acetate (500 mL×3). The combined organic layers were washed with water and brine, dried with NaSO4, filtered and concentrated to obtain a yellow oil. The crude material was purified by column chromatography on silica eluting with DCM in hexanes followed by ethyl acetate in hexanes. The product-containing fractions were combined and concentrated before triturating in ethyl acetate to obtain a solid which could be further recrystallized from acetonitrile to yield Monomer Example 1 (25.5 g, 52%) with 99.7% HPLC purity.

Solubility

Conjugated light-emitting polymers illustrated in Table 1 were formed by Suzuki polymerisation as described in WO 00/53656, the contents of which are incorporated herein by reference.

For each polymer, 50 mol % of a 2,7-diboronic ester fluorene monomer was reacted with 50 mol % of dibromo-monomers for forming the other repeat units of the polymer. In the cases where the molar percentage of fluorene repeat units in the polymer exceeds 50 mol %, the polymerisation mixture included both 2,7-diboronic ester fluorene monomer and 2,7-dibromofluorene monomer.

Polymers containing cesium carboxylate groups were formed by polymerisation of a corresponding ester followed by hydrolysis as disclosed in WO 2012/133229, the contents of which are incorporated herein by reference.

TABLE 1

| | | Solubility |
|---|---|---|
| | | in |
| | | methanol |
| Polymer | Structure | (mg/ml) |
| Comparative Polymer 1A | 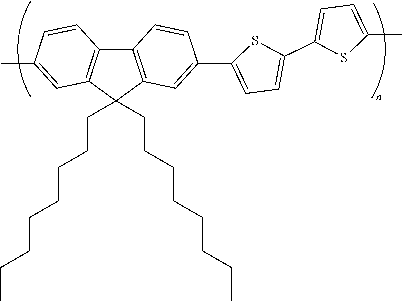 | Insoluble |
| Comparative Polymer 1B | 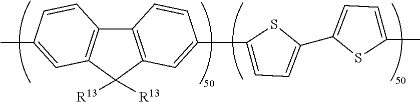 | Insoluble |
| Comparative Polymer 1C | 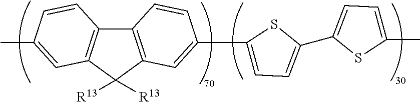 | <0.1 |
| Polymer Example 1 | 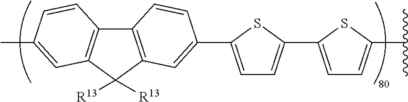 | >2.0 |
| | 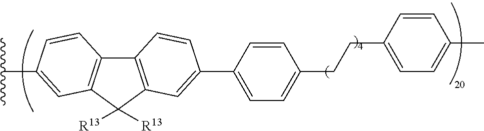 | |
| Polymer Example 2 | 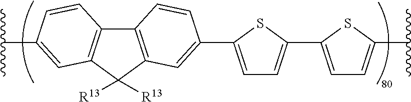 | >2.0 |
| | 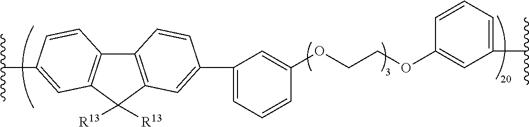 | |
| Polymer Example 3 | 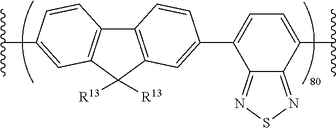 | No more than 0.5 mg/ml |
| | 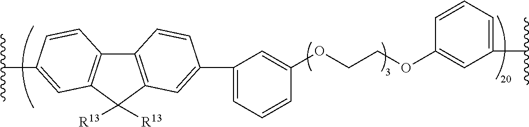 | |
| Polymer Example 4 | 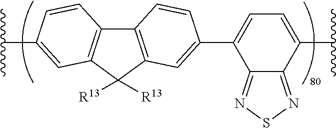 | >10 mg/ml |
| | 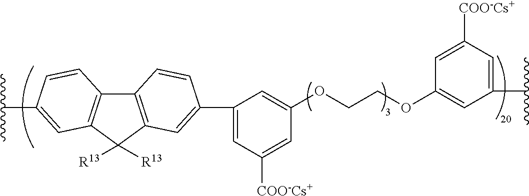 | |
| Polymer Example 5 | 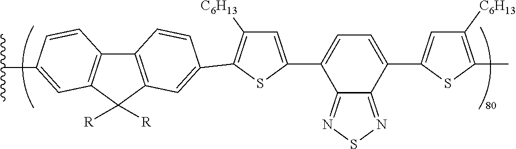 | |
| | 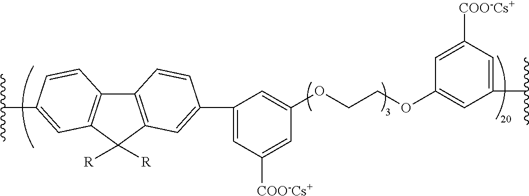 | |

R¹³=

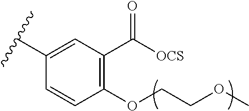

Comparative Polymer 1A is insoluble. Replacing the alkyl substituents of the fluorene group of Comparative Polymer 1A with polar substituents, as in Comparative Polymer 1B, did not result in solubility of the polymer.

Increasing the proportion of repeat units with polar substituents, as in Comparative Polymer 1C, did result in an improvement in solubility but results in undesirable absorption characteristics, as described below.

Polymer Example 1 is soluble in polar solvents.

Absorption

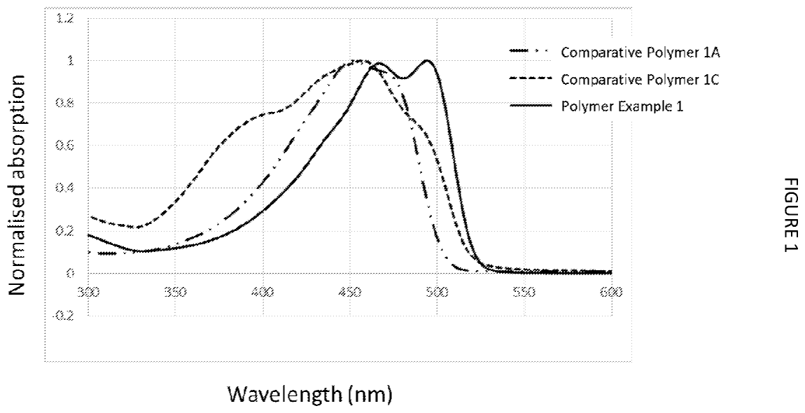

With reference to FIG. 1, Comparative Polymer 1A has a well-defined absorption peak. However, as set out above, this polymer is insoluble in polar solvents. Although Comparative Polymer 1C has improved solubility, as set out above, a significant absorption shoulder at about 390 nm is observed.

Introduction of a conjugation-breaking repeat unit results in a well-defined absorption peak. Without wishing to be bound by any theory, the absorption shoulder of Comparative Polymer 1C is due to conjugation of fluorene repeat units to one another.

Such fluorene-fluorene conjugation is prevented in Polymer Example 1 by the presence of the conjugation-breaking repeat unit.

1. A solution comprising a light-emitting polymer dissolved in a solvent comprising at least one solvent selected from C₁₋₈ alcohols and water, wherein the solution comprises a light-emitting polymer comprising:
a light-emitting repeat unit;
a repeat unit of formula Ar¹ wherein Ar¹ is an arylene repeat unit which is unsubstituted or substituted with one or more substituents; and
a repeat unit of formula (I): [symbol]
Ar²-CB-Ar³ [symbol] (I)
wherein Ar² and Ar³ each independently represent a C₆₋₂₀ arylene group or a 5-20 membered heteroarylene group which is unsubstituted or substituted with one or more substituents and CB represents a conjugation-breaking group which does not provide a conjugation path between Ar² and Ar³;
wherein the polymer has a solubility in water or a C₁₋₈ alcohol at 20° C. of at least 0.1 mg/ml.

2. The solution according to claim 1 wherein CB comprises at least one sp³ hybridised carbon atom separating Ar¹ and Ar².

3. The solution according to claim 1 wherein CB is a C₁₋₂₀ branched or linear alkylene group wherein one or more H atoms may be replaced with F and one or more non-adjacent C atoms of the alkylene group may be replaced with O, S, CO, COO or Si(R³)₂ wherein R³ in each occurrence is independently a C₁₋₂₀ hydrocarbyl group.

4. The solution according to claim 1 wherein Ar² and Ar³ are each independently phenylene which is unsubstituted or substituted with one or more substituents.

5. The solution according to claim 1 wherein at least one repeat unit of the polymer is substituted with at least one water or C₁₋₈ alcohol-solubilising substituent.

6. The solution according to claim 5 wherein the or each water or C₁₋₈ alcohol-solubilising substituent comprises an ionic group.

7. The solution according to claim 5 wherein Ar¹ is substituted with one or more water or C₁₋₈ alcohol-solubilising substituents.

8. (canceled)

9. (canceled)

10. (canceled)

11. The solution according to claim 1 wherein the light-emitting repeat unit comprises a heteroarylene group.

12. The solution according to claim 1 wherein the light-emitting repeat unit comprises an amine group.

13. The solution according to claim 1 wherein the light-emitting repeat unit comprises an arylene repeat unit substituted with the light-emitting group.

14. The solution according to claim 1 wherein Ar¹ is a C₆-C₁₄ arylene repeat unit.

15. The solution according to claim 14 wherein Ar¹ is a repeat unit of formula (IIb-1): 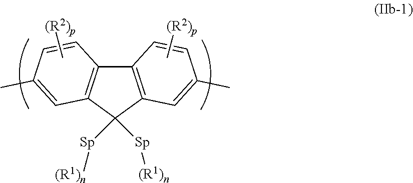
wherein Sp is a spacer group; R¹ in each occurrence is independently a polar group; each n is independently at least 1; each R² is independently a non-polar substituent; and p is 0 or a positive integer.

16. The solution according to claim 1 wherein at least one of Ar² and Ar³ is substituted with a group of formula -(Sp)ₘ-(R¹)ₙ wherein R¹ in each occurrence is independently a polar group selected from a non-ionic polar group and an ionic group; Sp is a spacer group; m is 0 or 1; n is 1 if m is 0; and n is at least 1 if m is 1.

17. The solution according to claim 1 wherein the polymer is a luminescent marker comprising a binding group configured to bind to a target material.

18. The solution according to claim 1 wherein the polymer is a luminescent marker precursor comprising a functional group capable of reacting with a functional group of a luminescent marker precursor according to claim 18 with a material for forming the binding group.

19. The solution according to claim 18 wherein the functional group is biotin.

20. (canceled)

21. (canceled)

22. A solution according to claim 1 wherein the concentration of the polymer in the solution is at least 0.1 mg/ml.

23. A method of forming a composite particle comprising a silica matrix and the light-emitting polymer, the method comprising polymerisation of a silane in the solution according to claim 1 or 2.

24. The method according to claim 19 wherein the composite particle is substituted with a binding group configured to bind to a target material.

25. (canceled)

26. (canceled)

27. (canceled)

28. A method of detecting a target analyte in a sample, the method comprising contacting the solution comprising the light-emitting marker according to claim 17 with a sample.

29. (canceled)
